(19) United States
(12) Patent Application Publication
(10) Pub. No.: US 2010/0283129 A1
(43) Pub. Date: Nov. 11, 2010

(54) SEMICONDUCTOR DEVICE AND METHOD FOR FABRICATING THE SAME

(76) Inventors: Michinari TETANI, Osaka (JP); Takashi Yui, Shiga (JP); Minoru Fujisaku, Kyoto (JP)

Correspondence Address: MCDERMOTT WILL & EMERY LLP, 600 13TH STREET, NW, WASHINGTON, DC, 20005-3096, US

(21) Appl. No.: 12/773,507

(22) Filed: May 4, 2010

(30) Foreign Application Priority Data
May 11, 2009 (JP) 2009-114662

(51) Int. Cl. H01L 23/544; H01L 21/77

(52) U.S. Cl. 257/620; 438/114; 257/E21.598; 257/E23.179

(57) ABSTRACT

An upper surface of a semiconductor substrate includes a first portion where a dielectric film is provided, and a second portion where the dielectric film is not provided, wherein the second portion is located in the periphery of the first portion. The upper surface of the semiconductor substrate is covered with a sealing resin.

### CROSS-REFERENCE TO RELATED APPLICATION

This application claims priority to Japanese Patent Application No. 2009-114662 filed on May 11, 2009, the disclosure of which including the specification, the drawings, and the claims is hereby incorporated by reference in its entirety.

### BACKGROUND

The present invention relates to semiconductor devices and methods for fabricating the same.

In recent years, as electronic equipment is downsized, and the functionality of the electronic equipment is enhanced, downsizing and greater packaging density of semiconductor devices (semiconductor packages) themselves are required. Due to these requirements, the number of terminals of the semiconductor devices has to be increased. As small packages having a large number of terminals, a variety of chip scale packages (CSPs, CSP is an acronym for chip scale package) have been developed.

Recently, particular attention has been drawn to wafer level CSPs (WLCSPs, WLCSP is an acronym for wafer level chip scale package) as a technique capable of providing ultimately small packages (whose size is substantially as small as that of chips). Such a wafer level CSP is fabricated according to the method described below. First, on the entirety of an upper surface of a semiconductor wafer on which a plurality of integrated circuits is formed, a film made of an insulating resin is formed. Next, on the film made of the insulating resin, interconnects (by which pad electrodes of the integrated circuits are electrically connected via contact holes to external terminals such as bumps) are formed. Then, in the last process, the semiconductor wafer is divided into chips.

Moreover, in the above semiconductor devices, as a material for an interlayer insulating film, a low dielectric constant (hereinafter referred to as “low-k”) material may be used (Japanese Patent Publication No. 2008-130886). Since the low-k material is weak in terms of mechanical properties, film formation conditions for the low-k film have to be devised so that no mechanical stress is applied to the low-k film, or handling of the low-k film after device formation has to be devised.

### SUMMARY

The upper surface of the semiconductor wafer is partitioned by, for example, a dicing line portion into a plurality of regions. Along the dicing line portion, the semiconductor wafer is divided into chips. To easily divide the semiconductor wafer, a dicing groove is usually formed in the dicing line portion prior to the process of dividing the semiconductor wafer into chips.

When the dicing groove is formed in the dicing line portion by irradiation with a laser beam, the low-k film, and the like formed in the dicing line portion are removed. At this time, if part of the low-k film is not removed but remains due to, for example, variations of the laser beam, cracks are formed in the remaining low-k film. If mechanical impact is exerted on the cracks, the cracks propagate to a sealing resin, and the like, and new cracks are formed in the sealing resin, and the like.

In a semiconductor device of the present invention, an upper surface of a semiconductor substrate includes a first portion where a dielectric film is provided, and a second portion where the dielectric film is not provided, wherein the second portion is located in the periphery of the first portion. The upper surface of such a semiconductor substrate is covered with a sealing resin.

A method for fabricating a semiconductor device of the present invention includes: (a) preparing a semiconductor wafer having a semiconductor element formed within a region partitioned by a dicing line portion; (b) providing a dielectric film on the semiconductor wafer; (c) forming a groove in the dielectric film in the dicing line portion by irradiation with a laser beam; (d) planarizing a bottom surface of the groove; and (e) providing a sealing resin on the dielectric film and in the groove having the bottom surface planarized in (d). Note that the term “planarized” means that the elevation difference between the most raised portion and the most recessed portion is, for example, 5 μm or less.

### BRIEF DESCRIPTION OF THE DRAWINGS

FIG. 1 is a partial cross-sectional view illustrating a configuration of a semiconductor device according to an embodiment of the present invention during fabrication.

FIG. 2 is a partial cross-sectional view illustrating the semiconductor device according to the embodiment of the present invention.

FIGS. 3A-3C are cross-sectional views sequentially illustrating processes in a method for fabricating the semiconductor device according to the embodiment of the present invention.

FIGS. 4A-4C are cross-sectional views sequentially illustrating processes in the method for fabricating the semiconductor device according to the embodiment of the present invention.

FIGS. 5A-5C are cross-sectional views sequentially illustrating processes in the method for fabricating the semiconductor device according to the embodiment of the present invention.

FIGS. 6A-6C are cross-sectional views sequentially illustrating processes in the method for fabricating the semiconductor device according to the embodiment of the present invention.

FIG. 7 is a partial cross-sectional view illustrating defects in a semiconductor device.

FIG. 8 is a cross-sectional view illustrating a process in a method for fabricating a semiconductor device according to another embodiment of the present invention.

### DETAILED DESCRIPTION

With reference to the drawings, embodiments of the present invention will be described in detail below. Note that the present invention is not limited to the embodiments below.

### First Embodiment

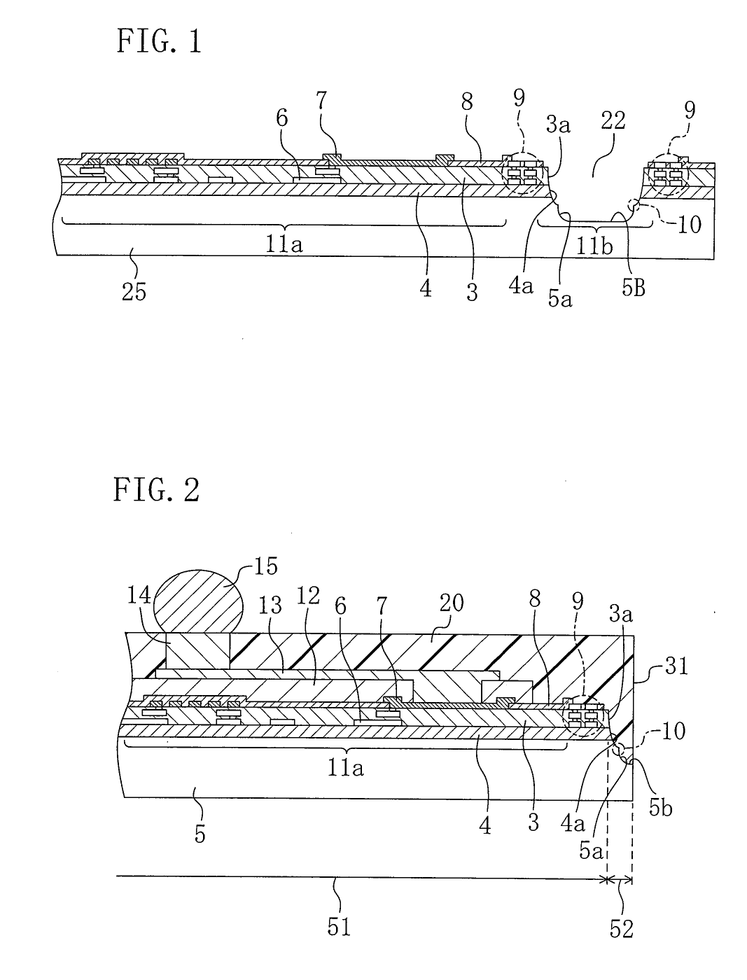

FIG. 1 is a partial cross-sectional view illustrating a configuration of a semiconductor device according to a first embodiment during fabrication. FIG. 2 is a partial cross-sectional view illustrating the semiconductor device according to the present embodiment.

In the semiconductor device according to the present embodiment, in an element region 11a of a semiconductor substrate 5, for example, a semiconductor element such as a metal oxide semiconductor (MOS)-type transistor, or a semiconductor element such as a diode formed by PN junction is provided. An upper surface of the semiconductor substrate 5 is covered with an interlayer insulating film 4, which protects the semiconductor element.

On the interlayer insulating film 4, a low-k film (dielectric film) 3 is formed. In the low-k film 3, signal lines 6 are formed. The signal lines 6 are electrically connected to the above semiconductor element, and are interconnects via which a signal is taken out of the semiconductor element. Moreover, on the low-k film 3, input/output lines 7 are formed. The input/output lines 7 are electrically connected to the signal lines 6, and are interconnects via which the signal, which the signal lines 6 have taken out of the above semiconductor element, is taken out to the outside of the semiconductor device. Note that the signal lines 6 and the input/output lines 7 are each formed by using a multilayer wiring technique. Moreover, part of an upper surface of the low-k film 3 on which the input/output lines 7 are not formed is covered with a surface protection film 8, by which the low-k film 3 and the signal lines 6 are electrically insulated from and protected from the external environment.

Rewiring members 13 are electrically connected to the input/output lines 7. Solder terminals 15 are electrically connected via posts 14 to the rewiring members 13. With this configuration, a signal from the above semiconductor element sequentially passes through the input/output lines 7, the rewiring members 13, the posts 14, and the solder terminals 15, and is taken out to the outside of the semiconductor device. Moreover, since the solder terminals 15 are electrically connected via the posts 14 to the rewiring members 13, the posts 14 can alleviate stress caused in the solder terminals 15, so that the metal fatigue life of the solder terminals 15 due to a temperature cycle can be prolonged. Therefore, it is possible to improve packaging reliability. Moreover, the rewiring members 13 and the posts 14 are protected by a sealing resin 20 from external impact or the atmosphere of the external environment. Note that an insulating film 12 is formed on the surface protection film 8, and the insulating film 12 and the rewiring members 13 are in contact with each other at their side surfaces.

On the semiconductor substrate 5, the element region 11a in which the semiconductor element is formed, and a peripheral portion relative to the element region 11a (a portion corresponding to a dicing line portion of a semiconductor wafer) are provided. Between the element region 11a and the peripheral portion, a seal ring 9 is provided, which can electrically and physically separate the element region 11a from the peripheral portion. Here, in the seal ring 9, a plurality of signal lines 6 (the number of the signal lines 6 is not limited to the number thereof illustrated in FIG. 1) is stacked on one another and electrically connected to each other.

The low-k film 3 is preferably made of any one of benzocyclobutene (BCB), fluorinated polyimide, polyolefin, a polyimide resin to which a filler is added, and organic polymer. With the thus formed low-k film 3, it is possible to prevent capacitance between the interconnects from being increased even if the distance between the interconnects is shortened due to miniaturization of the semiconductor device.

The semiconductor device according to the present embodiment will be further described.

The upper surface of the semiconductor substrate 5 includes a portion (first portion) 51 having the low-k film 3, and a portion (second portion) 52 having no low-k film. The second portion 52 includes a step portion 10.

Specifically, a side surface 3a of the low-k film 3 is located at an inner position relative to a side surface (device side surface) 31 of the semiconductor device. Thus, it is possible to physically insulate the low-k film 3 from the outside of the semiconductor device, so that the low-k film 3 can be prevented from being broken even if mechanical stress is applied to the semiconductor device. In addition, a side surface 4a of the interlayer insulating film 4 is also located at an inner position relative to the device side surface 31. Furthermore, a portion 5a of a side surface of the semiconductor substrate 5 which is located at an upper position (hereinafter referred to as “an upper portion of the side surface of the semiconductor substrate 5”) is located at an inner position relative to the device side surface 31, but projects from the side surface 3a of the low-k film 3 and the side surface 4a of the interlayer insulating film 4. Thus, between the side surface 4a of the interlayer insulating film 4 and the upper portion 5a of the side surface of the semiconductor substrate 5, the step portion 10 is formed.

Although only one upper portion 5a of the side surface of the semiconductor substrate 5 is illustrated in FIG. 1 and the like, the number of upper portions 5a of the side surface of the semiconductor substrate 5 is not limited to one. For example, the semiconductor substrate 5 may be formed to have steps such that the distance between the side surface of the semiconductor substrate 5 and the device side surface 31 in the second portion 52 increases from a lower surface toward the upper surface of the semiconductor substrate 5. In this case, the uppermost level of the steps may be connected to the side surface 4a of the interlayer insulating film 4.

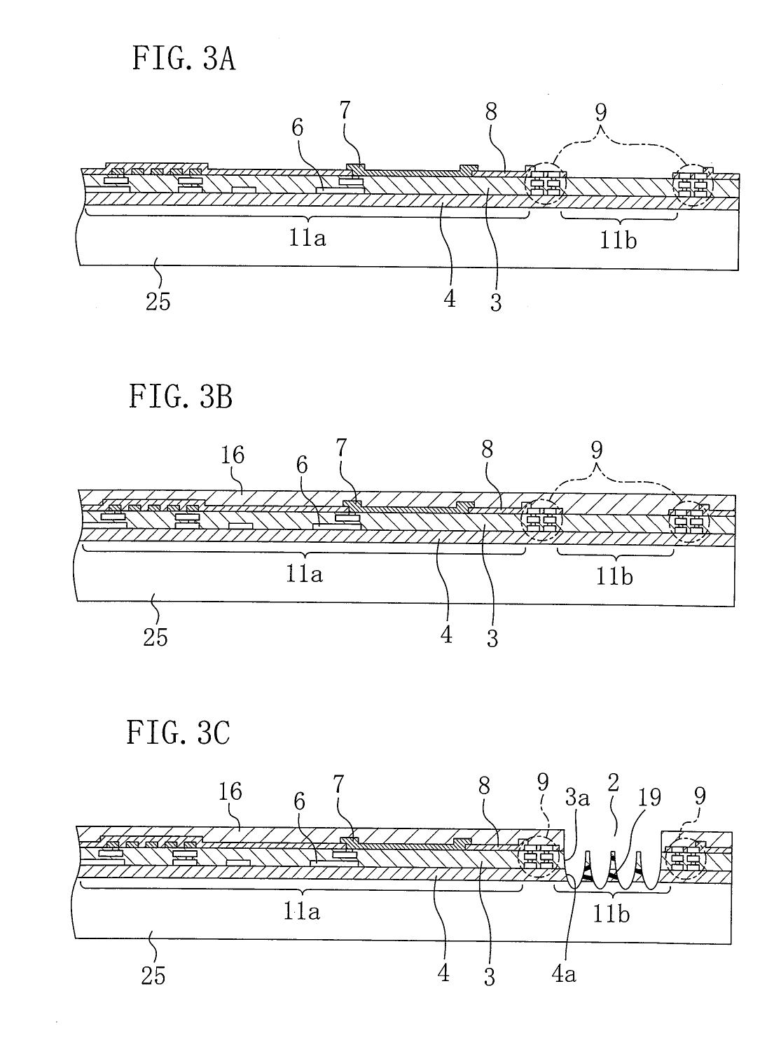

The second portion 52 includes a portion 5b of the upper surface of the semiconductor substrate 5 in which the low-k film 3 and the interlayer insulating film 4 are not formed (hereinafter referred to as “a portion of a bottom surface of a dicing groove”). The portion 5b of the bottom surface of the dicing groove is covered with the sealing resin 20, as the side surface 3a of the low-k film 3 and the side surface 4a of the interlayer insulating film 4 are covered. The portion 5b is more planar than the side surface 3a of the low-k film 3. Specifically, the portion 5b of the bottom surface of the dicing groove is formed by irradiating the peripheral portion relative to the element region 11a with a laser beam to form a groove 2 (illustrated in FIG. 3C) in the low-k film 3, and then planarizing a bottom surface of the groove 2. Thus, the portion 5b of the bottom surface of the dicing groove has no cracks caused by the irradiation with the laser beam. Therefore, the elevation difference in the portion 5b of the bottom surface of the dicing groove can be 5 μm or less. With this configuration, it is possible to prevent cracks from propagating from the low-k film 3 to the sealing resin 20 even if mechanical impact is exerted on the semiconductor device of the present embodiment.

In summary, in the semiconductor device according to the present embodiment, it is possible to prevent the low-k film 3 from being broken even if mechanical stress is applied to the semiconductor device.

Moreover, in the semiconductor device according to the present embodiment, no cracks remain in the portion 5b of the bottom surface of the dicing groove and in portions under the portion 5b. Thus, even if mechanical impact is exerted on the semiconductor device according to the present embodiment, it is possible to prevent cracks from propagating from the low-k film 3 to the sealing resin 20, and the like.

FIGS. 3A-6C are cross-sectional views sequentially illustrating processes in a method for fabricating the semiconductor device according to the present embodiment.

First, a semiconductor wafer 25 illustrated in FIG. 3A is prepared (step (a)). Here, an upper surface of the semiconductor wafer 25 is partitioned by a dicing line portion 11b into a plurality of regions (element regions 11a). In each of the element regions 11a, a semiconductor element such as a MOS-type transistor or a semiconductor element such as a diode formed by PN junction is provided. After that, on the entirety of the upper surface of the semiconductor wafer 25, an interlayer insulating film 4 and a low-k film 3 are sequentially formed (step (b)). In each element region 11a, signal lines 6 are formed in the low-k film 3, and input/output lines 7 and a surface protection film 8 are formed on the low-k film 3. The low-k film 3 in the dicing line portion 11b is not covered with the input/output lines 7 and the surface protection film 8, and thus is exposed. Moreover, between each element region 11a and the dicing line portion 11b, a seal ring 9 is provided.

Next, in the process illustrated in FIG. 3B, a protection film 16 is formed on the entirety of the upper surface of the semiconductor wafer 25 by, for example, spin coating. Here, since the concavo-convex shape of the surface protection film 8 differs from device to device, the thickness of the protection film 16 is preferably set in consideration of variations in concavo-convex shape of the surface protection film 8. In other words, the protection film 16 is preferably formed to have an even upper surface regardless of the concavo-convex shape of the surface protection film 8.

Next, in the process illustrated in FIG. 3C, the dicing line portion 11b is irradiated with a laser beam to form a groove 2 (step (c)). At this time, in consideration of the subsequent steps, it is preferable to form a plurality of grooves 2. In this step, not only the low-k film 3 but also the interlayer insulating film 4 directly under the low-k film 3 is removed. However, due to variations in laser processing, it is often the case that part of the low-k film 3 and the interlayer insulating film 4 is removed, and cracks 19 are formed in the low-k film 3 and the interlayer insulating film 4 which are not removed.

Here, since the low-k film 3 is a weak film, the low-k film 3 may be broken if mechanical stress is applied to the semiconductor device. However, forming the groove 2 in the low-k film 3 in the dicing line portion 11b allows, in the fabricated semiconductor device, a side surface 3a of the low-k film 3 to be formed at an inner position relative to a side surface of the semiconductor device. Thus, even if mechanical stress is applied to the semiconductor device, it is possible to prevent the low-k film 3 from being broken.

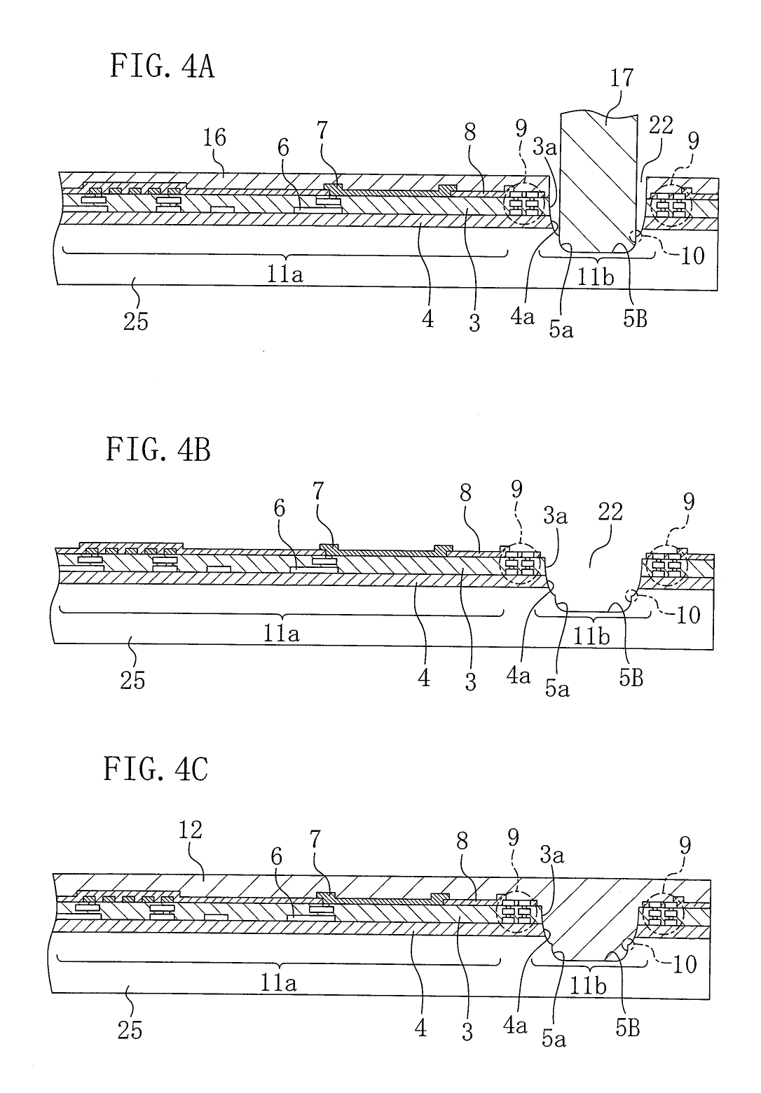

Next, in the process illustrated in FIG. 4A, using a dicing blade 17, the low-k film 3 and the interlayer insulating film 4 in which the cracks 19 are formed are removed (step (d)). A dicing groove 22 is thus formed in the dicing line portion 11b. At this time, the low-k film 3 and the interlayer insulating film 4 in which the cracks 19 are formed are cut by a tip of the dicing blade 17. Thus, the tip of the dicing blade 17 preferably has a shape capable of removing the low-k film 3 and the interlayer insulating film 4 in which the cracks 19 are formed. Specifically, the tip of the dicing blade 17 may have a shape which forms almost no unevenness in the portion to be diced. In other words, the tip of the dicing blade 17 may have a shape which forms a planar portion to be diced.

A side surface of the thus formed dicing groove 22 includes the side surface 3a of the low-k film 3, a side surface 4a of the interlayer insulating film 4, and an upper portion 5a of a side surface of a semiconductor substrate 5. The side surface 3a of the low-k film 3 and the side surface 4a of the interlayer insulating film 4 are surfaces formed by irradiation with a laser beam as illustrated in FIG. 3C. The upper portion 5a of the side surface of the semiconductor substrate 5 is a surface formed by cutting using the dicing blade 17 as illustrated in FIG. 4A. Moreover, a bottom surface 5B of the dicing groove 22 is part of an upper surface of the semiconductor substrate 5, and is a surface formed by cutting using the dicing blade 17. Thus, the bottom surface 5B of the dicing groove 22 can be more planar than the side surface 3a of the low-k film 3 and than the side surface 4a of the interlayer insulating film 4. In other words, the elevation difference of the bottom surface 5B of the dicing groove 22 can be 5 pm or less.

Moreover, as shown in FIG. 4A, when the width of the tip of the dicing blade 17 is smaller than opening of the groove 2, the upper portion 5a of the side surface of the semiconductor substrate 5 projects from the side surface 3a of the low-k film 3 and the side surface 4a of the interlayer insulating film 4 toward the inside of the dicing groove 22. Thus, in this case, between the side surface 4a of the interlayer insulating film 4 and the upper portion 5a of the side surface of the semiconductor substrate 5, a step portion 10 is formed.

Note that in the process illustrated in FIG. 4A, the low-k film 3 and the interlayer insulating film 4 in which the cracks 19 are formed may be removed by using dicing blades whose tips have different widths from each other. In such a case, a dicing blade having a narrower tip is preferably used as the number of the times increases that the low-k film 3 and the interlayer insulating film 4 in which the cracks 19 are formed are removed.

Next, in the process illustrated in FIG. 4B, the protection film 16 is removed by, for example, cleaning.

Next, in the process illustrated in FIG. 4C, a material for an insulating film 12 is applied to the entirety of the upper surface of the semiconductor wafer 25 by, for example, spin coating. At this time, the thickness of the insulating film 12 applied to the entirety of the upper surface of the semiconductor wafer 25 is preferably adjusted such that the thickness of the insulating film 12 after thermal curing of the material for the insulating film 12 is greater than or equal to 4 μm and less than or equal to 8 μm. Moreover, when the material for the insulating film 12 has photosensitivity, application and removal of a photosensitive material can be dispensed with, so that it is possible to shorten the process of forming the insulating film 12. In addition, the material for the insulating film 12 having photosensitivity provides the advantage that the step portion can be prevented from having an overhang shape in cross section.

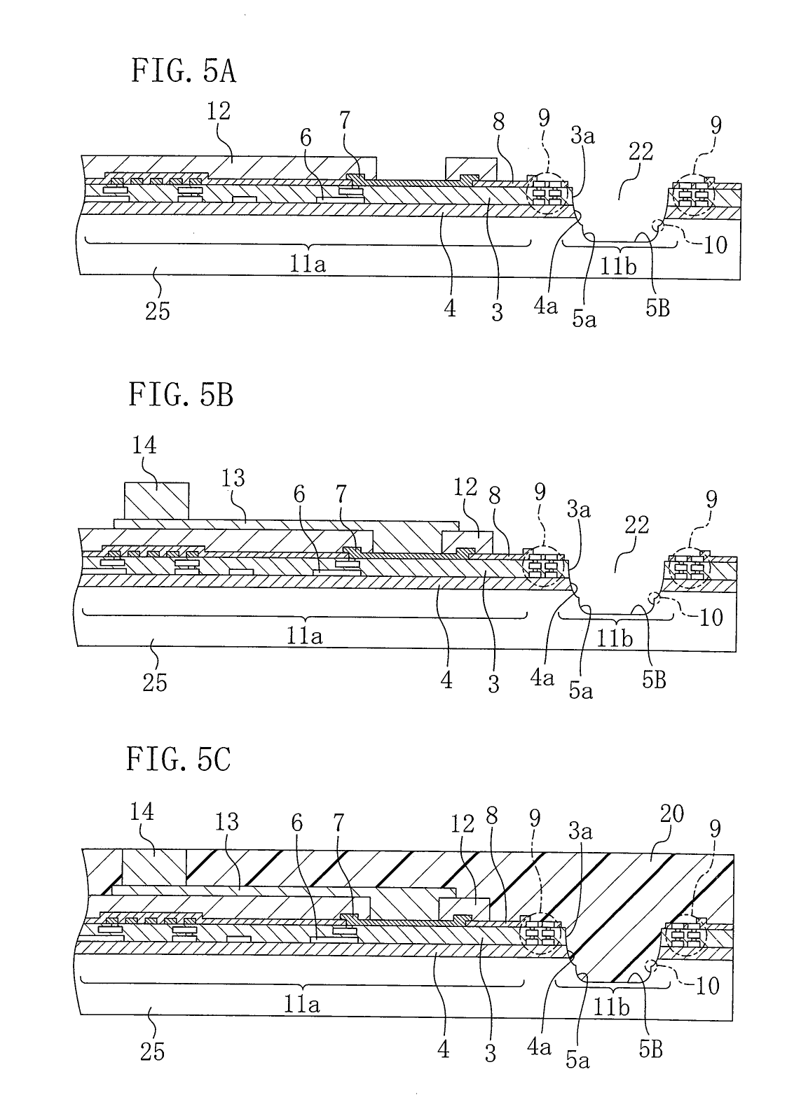

Next, in the process illustrated in FIG. 5A, the insulating film 12 is patterned by using, for example, a photo printing technique, and then is cured at 280° C. to 380° C.

Next, in the process illustrated in FIG. 5B, rewiring members 13 and posts 14 are formed by a photo printing technique and plating. At this time, as a photosensitive resist material used for the photo printing technique, it is preferable to select a material which can be applied at a thickness of greater than or equal to 10 μm and less than or equal to 20 μm. As an ultraviolet exposure device, it is preferable to select a device which is capable of providing an exposure energy of, for example, about 2400 mJ/cm² in consideration of a large thickness of a photosensitive resist, or it is preferable to select a device which has a bottom surface perpendicular to a side surface of the photosensitive resist. Moreover, the rewiring members 13 and the posts 14 are preferably formed by plating of, for example, Cu. Furthermore, the thickness of the rewiring members 13 is required to be greater than or equal to 5 μm and less than or equal to 10 and is preferably selected in consideration of the reduction in thickness of a Cu film in the subsequent processes.

Next, in the process illustrated in FIG. 5C, a material for a sealing resin 20 is applied to the entirety of the upper surface of the semiconductor wafer 25 by a printing process or a molding process, and then is cured (step (e)). At this time, the material for the sealing resin 20 is filled in the dicing groove 22. In this way, the semiconductor element, and the like can be protected from external mechanical stress. After the material for the sealing resin 20 is cured, the posts 14 and the sealing resin 20 are cut by grinding so that the thickness of the posts 14 equals the designed value.

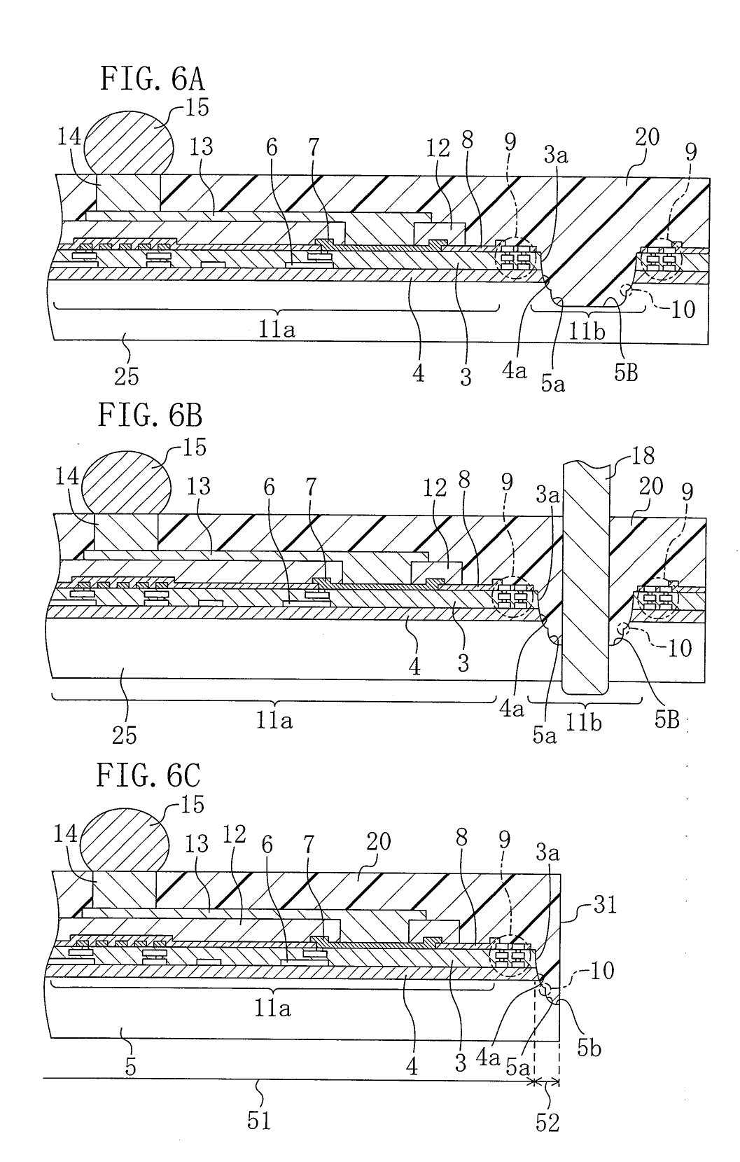

Next, in the process illustrated in FIG. 6A, solder terminals 15 are connected to the posts 14. Note that the solder terminals 15 serve as electrode terminals when the semiconductor device exchanges signals with external devices, and serve as connection terminals when the semiconductor device is connected to a mounting substrate.

Next, in the process illustrated in FIG. 6B, using a dicing blade 18, the semiconductor wafer 25 is cut into individual semiconductor substrates 5 along the dicing line portion 11b. In this way, a semiconductor device illustrated in FIG. 6C can be fabricated.

In summary, in the method for fabricating the semiconductor device according to the present embodiment, the dicing line portion 11b is irradiated with a laser beam to form the groove 2 in the low-k film 3, so that it is possible to form the side surface 3a of the low-k film 3 at an inner position relative to the device side surface 31. Thus, in a semiconductor device fabricated by using the method for fabricating the semiconductor device according to the present embodiment, it is possible to prevent the low-k film 3 from being broken even if mechanical stress is applied to the semiconductor device.

Moreover, in the method for fabricating semiconductor device according to the present embodiment, after the dicing line portion 11b is irradiated with a laser beam to form the groove 2 in the low-k film 3, a bottom surface of the groove 2 is cut by using the dicing blade 17. This can remove the low-k film 3 and the interlayer insulating film 4 in which the cracks 19 are formed, so that it is possible to prevent the cracks 19 from remaining in the fabricated semiconductor device. Thus, in the semiconductor device fabricated by using the method for fabricating the semiconductor device according to the present embodiment, it is possible to prevent cracks from propagating from the low-k film 3 to the sealing resin 20, and the like even if mechanical impact is exerted on the semiconductor device.

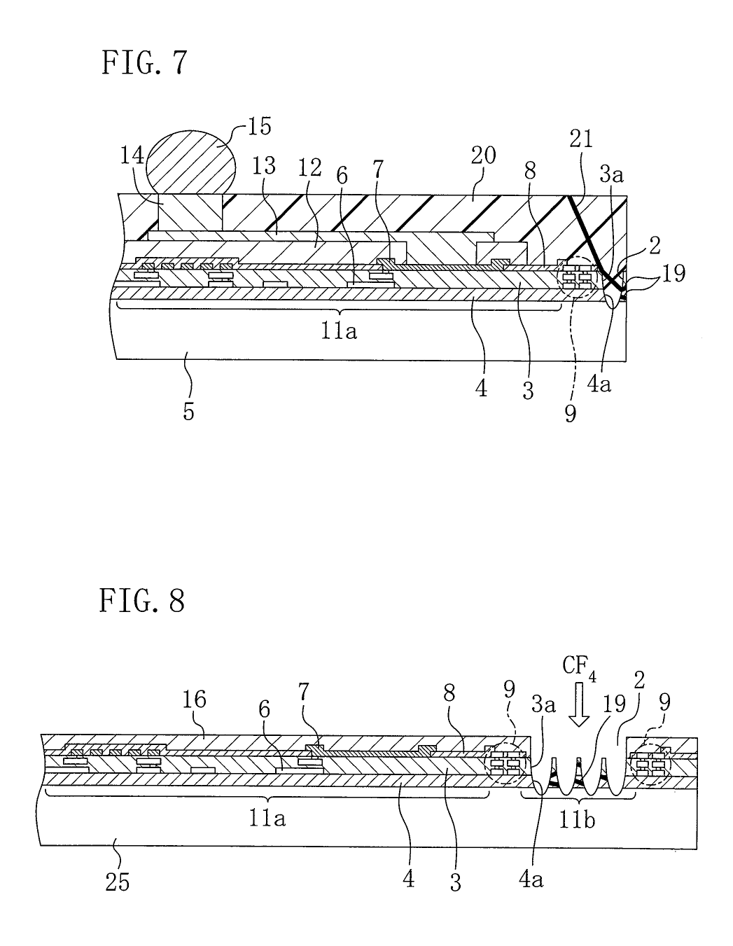

Note that when a semiconductor device is fabricated without undergoing the process illustrated in FIG. 4A, defects as shown in FIG. 7 may be caused. FIG. 7 is a partial cross-sectional view illustrating a semiconductor device, and with reference to FIG. 7, the defects will be described. When a semiconductor device is fabricated without undergoing the process illustrated in FIG. 4A, cracks 19 remain in the fabricated semiconductor device. If mechanical impact is exerted on the cracks 19, the cracks 19 propagate to a sealing resin 20, forming new cracks 21 in the sealing resin 20.

### Second Embodiment

FIG. 8 is a cross-sectional view illustrating a process in a method for fabricating a semiconductor device according to a second embodiment of the present invention.

The present embodiment is different from the first embodiment in a method for removing the low-k film 3 and the interlayer insulating film 4 in which the cracks 19 are formed. Aspects different from those of the first embodiment will mainly be described below.

In the method for fabricating the semiconductor device according to the present embodiment, the processes illustrated in FIGS. 3A-3C in the method for fabricating the semiconductor device according to the first embodiment are first performed. After that, the process illustrated in FIG. 8 is performed.

Specifically, in the present embodiment, a gas (e.g., CF₄) capable of reacting with a Si compound is used instead of the dicing blade 17 in order to remove the low-k film 3 and the interlayer insulating film 4 in which the cracks 19 are formed. The low-k film 3 and the interlayer insulating film 4 in which the cracks 19 are formed may be chemically removed as in the present embodiment. After that, the processes illustrated in FIGS. 4B-6C in the method for fabricating the semiconductor device according to the first embodiment are performed.

In the method for fabricating the semiconductor device according to the present embodiment, the low-k film 3 and the interlayer insulating film 4 in which the cracks 19 are formed can be removed as in the method for fabricating the semiconductor device according to the first embodiment. Thus, in the present embodiment, it is possible to obtain advantages similar to those of the first embodiment.

What is claimed is:

1. A semiconductor device comprising:
a semiconductor substrate;
a dielectric film provided on the semiconductor substrate; and
a sealing resin, wherein
an upper surface of the semiconductor substrate has a first portion where the dielectric film is provided, and a second portion where the dielectric film is not provided in a periphery of the first portion, and
the upper surface of the semiconductor substrate is covered with the sealing resin.

2. The semiconductor device of claim 1, wherein
the second portion has level differences in a form of steps.

3. The semiconductor device of claim 1, wherein
a side surface of the dielectric film is located at an inner position relative to a device side surface, and is formed by irradiation with a laser beam.

4. The semiconductor device of claim 1, wherein
the dielectric film is made of any one of BCB, fluorinated polyimide, polyolefin, a polyimide resin to which a filler is added, and organic polymer.

5. A method for fabricating a semiconductor device comprising:
(a) preparing a semiconductor wafer having a semiconductor element formed within a region partitioned by a dicing line portion;
(b) providing a dielectric film on the semiconductor wafer;
(c) forming a groove in the dielectric film in the dicing line portion by irradiation with a laser beam;
(d) planarizing a bottom surface of the groove; and
(e) providing a sealing resin on the dielectric film and in the groove having the bottom surface planarized in (d).

6. The method of claim 5, wherein
the bottom surface of the groove is cut in (d).

7. The method of claim 5, wherein
a gas which reacts with a material for the semiconductor substrate is used to perform (d).

8. The method of claim 5, wherein
in (c), part of the dielectric film in the dicing line portion is removed, and
in (d), the dielectric film remaining after (c) is removed.
